(19) United States
(12) Patent Application Publication
(10) Pub. No.: US 2026/0304657 A1
(43) Pub. Date: Oct. 1, 2026

(54) DISPLAY MODULE, MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventor: Ching Chieh FU, Beijing (CN)

(21) Appl. No.: 18/992,966

(22) PCT Filed: May 20, 2024
(86) PCT No.: PCT/CN2024/094297

§ 371 Date: Jan. 9, 2025

(30) Foreign Application Priority Data
Jun. 12, 2023 (CN) 202310694033.X

(51) Int. Cl. H05K 5/03; H05K 5/02

(52) U.S. Cl. CPC H05K 5/03; H05K 5/0217

(57) ABSTRACT

Provided is a display module. The display module includes: a display panel including a bending region and a non-bending region; a support layer disposed on a side, away from a light-exiting surface of the display panel, of the display panel; and a protective cover plate disposed on a side of the light-exiting surface of the display panel. The protective cover plate includes a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed at a side, close to the display panel, of at least one release layer of the plurality of release layers.

### CROSS-REFERENCE TO RELATED APPLICATIONS

This application is a U.S. national stage of international application No. PCT/CN2024/094297, filed on May 20, 2024, which claims priority to Chinese Patent Application No. 202310694033.X, filed on Jun. 12, 2023, entitled “DISPLAY MODULE, PREPARATION METHOD THEREOF AND DISPLAY DEVICE,” the disclosures of which are herein incorporated by reference in their entireties.

### TECHNICAL FIELD

The present disclosure relates to the field of display technologies, and in particular, relates to a display module, a manufacturing method therefor, and a display device.

### BACKGROUND

In recent years, with the development of display technologies, a series of foldable display products (such as foldable cell phones) that can be easily carried by a user have emerged.

### SUMMARY

The present disclosure provides a display module, a manufacturing method therefor, and a display device. The technical solutions are as follows.

According to an aspect, a display module is provided. The display module includes:
a display panel, wherein the display panel includes a bending region and a non-bending region surrounding the bending region;
a support layer disposed on a side, away from a light-exiting surface of the display panel, of the display panel, wherein the support layer includes a first support portion disposed on a side of the bending region and a second support portion disposed on a side of the non-bending region, the first support portion including a skeleton region and being spaced apart from the display panel, and the second support portion being in contact with the display panel; and
a protective cover plate disposed on a side of the light-exiting surface of the display panel, wherein the protective cover plate includes a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed at a side, close to the display panel, of at least one release layer of the plurality of release layers.

In some embodiments, a material of the second hardened coating layer is the same as a material of the first hardened coating layer.

In some embodiments, the second hardened coating layer has a thickness less than a thickness of the first hardened coating layer.

In some embodiments, the thickness of the first hardened coating layer ranges from 5 μm to 8 μm; and the thickness of the second hardened coating layer ranges from 3 μm to 4 μm.

In some embodiments, the protective cover plate includes a second hardened coating layer disposed at a side, close to the display panel, of each of the plurality of release layers.

In some embodiments, the protective cover plate includes a first release layer and a second release layer sequentially stacked in a direction close to the display panel.

In some embodiments, the protective cover plate includes a first hardened coating layer disposed on a side, away from the display panel, of the first release layer, and a second hardened coating layer disposed on a side, close to the display panel, of the first release layer.

In some embodiments, the protective cover plate includes a first hardened coating layer disposed on a side, away from the display panel, of the first release layer, and a second hardened coating layer disposed on a side, close to the display panel, of the second release layer.

In some embodiments, the protective cover plate includes a first cover layer and a second cover layer sequentially stacked in a direction close to the display panel.

In some embodiments, both a material of the first cover layer and a material of the second cover layer include a transparent flexible material, and the material of the first cover layer is different from the material of the second cover layer.

In some embodiments, the material of the first cover layer includes transparent glass; and the material of the second cover layer includes colorless polyimide.

In some embodiments, a thickness of the second cover layer is less than a thickness of the first cover layer.

In some embodiments, the thickness of the first cover layer is greater than or equal to 30 μm; and the thickness of the second cover layer ranges from 2 μm to 4 μm.

In some embodiments, a material of any one of the plurality of the release layers includes polyethylene terephthalate.

In some embodiments, the display panel includes a flexible substrate and a display screen sequentially stacked in a direction away from the support layer; and

the display module further includes:

a first adhesive layer, disposed between two adjacent film layers in the display panel and the protective cover plate and configured to adhere the two adjacent film layers; and

a second adhesive layer, disposed between two adjacent film layers in the display panel and the support layer and configured to adhere the two adjacent film layers;

wherein an orthographic projection of a second adhesive layer disposed between the flexible substrate and the support layer on the display panel is overlapped with an orthographic projection of the second support portion of the support layer on the display panel and is not overlapped with an orthographic projection of the first support portion of the support layer on the display panel, and the second adhesive layer is configured to adhere the flexible substrate to the second support portion of the support layer.

In some embodiments, the display module further includes:

a waterproof protective film disposed between the second support portion and the flexible substrate.

In some embodiments, the first adhesive layer includes a transparent optically clear adhesive; and the second adhesive layer includes a pressure-sensitive adhesive.

In some embodiments, a material of the support layer includes stainless steel; and an orthographic projection of the first support portion on the display panel is reticulate.

According to another aspect, a method for manufacturing a display module is provided. The method is applicable to manufacturing the display module as described in the above aspect, and the method includes:
providing a display panel, wherein the display panel includes a bending region and a non-bending region surrounding the bending region;
forming a support layer on a side, away from a light-exiting surface of the display panel, of the display panel, wherein the formed support layer includes a first support portion disposed on a side of the bending region and a second support portion disposed on a side of the non-bending region, the first support portion including a skeleton region and being spaced from the display panel, and the second support portion being in contact with the display panel; and
forming a protective cover plate on a side of the light-exiting surface of the display panel, wherein the formed protective cover plate includes a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed on a side, close to the display panel, of at least one release layer of the plurality of release layers.

According to another aspect, a display device is provided. The display device includes: a power supply assembly and a display module as described in the above aspect;
wherein the power supply assembly is coupled to the display module and is configured to supply power to the display module.

### BRIEF DESCRIPTION OF DRAWINGS

In order to describe the technical solutions in the embodiments of the present disclosure more clearly, the following briefly introduces the accompanying drawings required for describing the embodiments. Apparently, the accompanying drawings in the following description show merely some embodiments of the present disclosure, and a person skilled in the art can still derive other drawings from these accompanying drawings without creative efforts.

FIG. 1 is a schematic diagram of a film layer structure of a display module according to some embodiments of the present disclosure;

FIG. 2 is a schematic diagram of a film layer structure of another display module according to some embodiments of the present disclosure;

FIG. 3 is a schematic diagram of a film layer structure of yet another display module according to some embodiments of the present disclosure;

FIG. 4 is a schematic partial diagram of a film layer of a display module on the basis of the film layer structure shown in FIG. 3;

FIG. 5 is a schematic diagram of a film layer structure of still another display module according to some embodiments of the present disclosure;

FIG. 6 is a schematic partial diagram of a film layer of a display module on the basis of the film layer structure shown in FIG. 5;

FIG. 7 is a schematic partial diagram of a film layer of a display module on the basis of the film layer structure shown in FIG. 2;

FIG. 8 is a schematic diagram of a warping magnitude comparison of four corners according to some embodiments of the present disclosure;

FIG. 9 is a schematic diagram of a warping magnitude comparison of edges according to some embodiments of the present disclosure;

FIG. 10 is a schematic diagram of a film layer structure of still another display module according to some embodiments of the present disclosure;

FIG. 11 is a flowchart of a method for manufacturing a display module according to some embodiments of the present disclosure; and

FIG. 12 is a schematic structural diagram of a display device according to some embodiments of the present disclosure.

### DETAILED DESCRIPTION

To make the objectives, technical solutions, and advantages of the present disclosure clearer, the embodiments of the present disclosure are further described hereinafter with reference to the accompanying drawings.

In the related art, a foldable display product generally includes a foldable display panel, and a support portion disposed on a side, away from a light-exiting surface of the foldable display panel, of the foldable display panel and configured to support the foldable display panel. The foldable display panel includes a bending region and a non-bending region. The support portion is generally made of steel use stainless (SUS), a portion, disposed on a side of the bending region, of the support portion has a skeleton structure and is spaced apart from the foldable display panel, and a portion, disposed on a side of the non-bending region, of the support portion is in contact with the foldable display panel. In this way, the foldable display panel is better supported, and at the same time, the weight of the product is reduced and the folding effect is ensured.

Currently, in the foldable display product, a portion, disposed in a bending region of the foldable display panel, of the support portion configured to support the foldable display panel is spaced apart from the foldable display panel, which results in the foldable display product being uneven at that position, and in turn results in the foldable display product being prone to warping. Therefore, the foldable display panel, when reflecting light from the outside, is likely to arch visibly, thereby having the problem of light and shadow being unsmooth. Based on this, embodiments of the present disclosure provide a new display module that can solve the problem of light and shadow being unsmooth which easily occurs on the foldable display module in the related art.

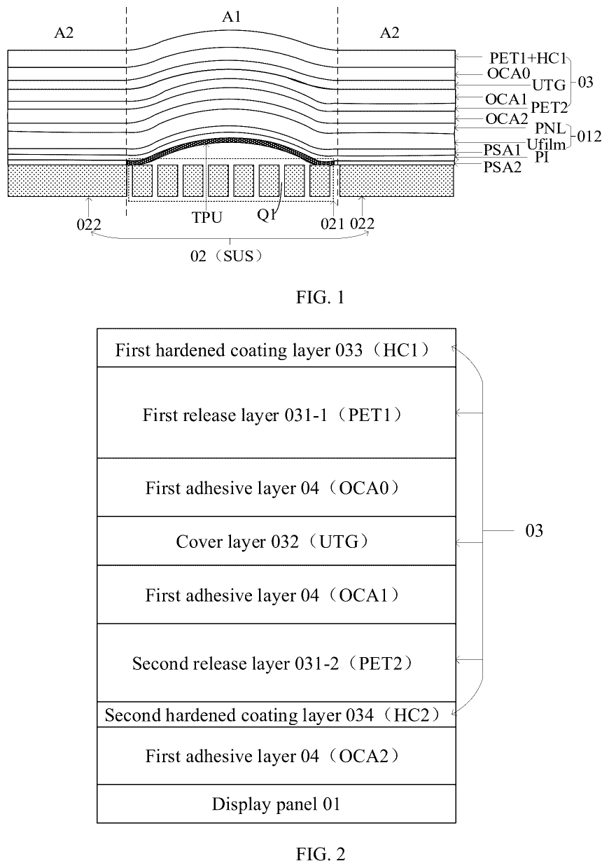

FIG. 1 is a schematic diagram of a film layer structure of a display module according to some embodiments of the present disclosure. FIG. 2 is a schematic diagram of a film layer structure of another display module according to some embodiments of the present disclosure. As can be seen from FIGS. 1 and 2, the display module according to the embodiments of the present disclosure includes: a display panel 01, a support layer 02 disposed on a side, away from a light-exiting surface of the display panel 01, of the display panel 01, and a protective cover plate 03 disposed on a side of the light-exiting surface of the display panel 01.

It should be noted that the side of the light-exiting surface of the display panel 01 refers to a side that displays a picture, and accordingly, the side away from the light-exiting surface of the display panel 01 is also referred to as a back surface of the display panel 01.

Still referring to FIGS. 1 and 2, it can be seen that the display panel 01 includes a bending region A1 and a non-bending region A2 surrounding the bending region A1. It can be seen that, in some embodiments, the display panel 01 is a foldable display panel, and the display module including the display panel 01 is a foldable display module. It is to be noted that the bending region A1 and the non-bending region A2 herein are different portions of the same substrate in the display panel 01.

In some embodiments, still referring to FIGS. 1 and 2, it can be seen that, in the display module according to the embodiments of the present disclosure, the support layer 02 includes a first support portion 021 disposed on a side of the bending region A1 and a second support portion 022 disposed on a side of the non-bending region A2. Further, the first support portion 021 includes a skeleton region Q1 (e.g., with a plurality of through-holes) and is spaced apart from (i.e., does not come into contact with) the display panel 01. The second support portion 022 is in contact with the display panel 01. Because the first support portion 021 disposed on a side of the bending region A1 requires a patterning design of skeletonization, the region, corresponding to the bending region A1, of the first support portion 021 is also referred to as a patterning range.

For the display module including the above-described support layer 02, once the problem of unevenness of the film layer occurs, upwarping shown in FIG. 1 occurs on the display panel 01 at the range of the bending region A1. That is, the display panel 01 bulges towards a side away from the first support portion 021, and the bulge of the display panel 01 at the ends of the first support portion 021 near the second support portion 022 is less than the bulge at the center position of the first support portion 021, wherein the center position of the first support portion 021 refers to a position of a central axis. The up-warping shown in FIG. 1 further leads to an arching phenomenon at the two ends of the first support portion 021 near the second support portion 022, thereby forming a visible and obvious arching phenomenon at the time of the display module reflecting external light in a dark state, and resulting in the problem of light and shadow being unsmooth for the display module.

Still referring to FIGS. 1 and 2, it can be seen that the protective cover plate 03 at least includes: a plurality of release layers 031 sequentially stacked in a direction away from the display panel 01, at least one cover layer 032 disposed between two adjacent release layers 031 of the plurality of release layers 031, and a first hardened coating layer (HC) 033 disposed on a side, away from the display panel 01, of the plurality of release layers 031, the hardened coating layer being also referred to as a HC layer.

In addition, referring to FIG. 2, it can also be seen that another display module according to some embodiments of the present disclosure further includes a second hardened coating layer 034 disposed on a side, close the display panel 01, of at least one release layer of the plurality of release layers 031. For the purpose of differentiation, the first hardened coating layer 033 is referred to as an HC1 layer, and the second hardened coating layer 034 is referred to as an HC2 layer.

On the one hand, on the basis of including a plurality of cover layers 032, the warping forms of the different cover layers 032 can mutually counteract the shrinkage of the first hardened coating layer 033 and reduce the warping of the protective cover plate 03. On the other hand, on the basis of disposing the second hardened coating layer 034, the purpose of stress offsetting can be achieved to similarly reduce the warping of the protective cover plate 03. On the basis of reducing the warping of the protective cover plate 03, it is possible to make the display module as a whole relatively flat, thereby avoiding the problem of light and shadow being unsmooth. That is, compared to the display module shown in FIG. 1, the warping of the protective cover plate 03 in FIG. 2 is reduced, and the display module is flatter.

In summary, the embodiments of the present disclosure provide a display module. The display module includes: a display panel including a bending region and a non-bending region, and a protective cover plate and a support layer respectively disposed on a side of a light-exiting surface and a side of a back surface of the display panel. The protective cover plate includes not only a plurality of release layers sequentially stacked and a first hardened coating layer disposed on a side, away from the display panel, of the plurality of release layers, but also at least one cover layer disposed between two adjacent release layers and a second hardened coating layer disposed on a side, close to the display panel, of at least one release layer. In this way, stress offsetting is achieved by virtue of the warping of the cover layer and the second hardened coating layer and the warping of the first hardened coating layer, and thus a relatively flat protective cover plate is formed. On the basis of the formation of the flat protective cover plate, the problem that the display module is prone to warping is alleviated, and no visible and obvious arch occurs at the time of the display module reflecting external light, thereby effectively avoiding the problem of light and shadow being unsmooth in the display module.

In some embodiments of the present disclosure, according to the sequence of the manufacturing processes, the at least one cover layer 032 of the protective cover plate 03 and the film layers disposed on the side, away from the display panel 01, of the at least one cover layer 032 are collectively referred to as a first protective cover plate cover1, and film layers disposed between the at least one cover layer 032 and the display panel 01 are collectively referred to as a second protective cover plate cover2. In some embodiments, the first protective cover plate cover1, and the second protective cover plate cover2, are formed in different manufacturing processes. Of course, the above are only schematic illustrations.

In some embodiments, referring to FIGS. 1 and 2, it can be seen that the protective cover plate 03 according to the embodiments of the present disclosure further includes one cover layer 032.

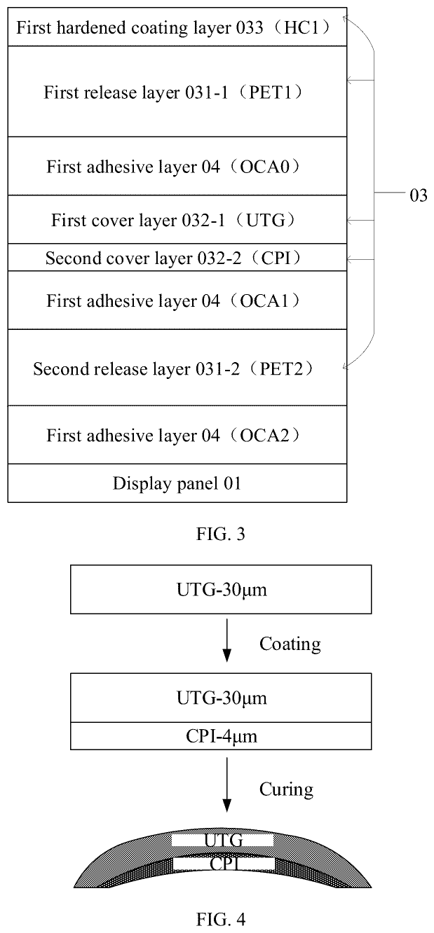

Alternatively, as can be seen with reference to the partial film layer diagrams shown in FIGS. 3 and 4, the protective cover plate 03 according to the embodiments of the present disclosure includes: a first cover layer 032-1 and a second cover layer 032-2 sequentially stacked in a direction close to the display panel 01, i.e. two cover layers 032 in total.

Moreover, in some embodiments, both a material of the first cover layer 032-1 and a material of the second cover layer 032-2 include a transparent flexible material, and the material of the first cover layer 032-1 and the material of the second cover layer 032-2 are different.

In some embodiments, the material of the first cover layer 032-1 includes transparent glass. The material of the second cover layer 032-2 includes colorless polyimide (CPI). Accordingly, the first cover layer 032-1 is also referred to as an ultra-thin flexible glass (UTG) cover, and the second cover layer 032-2 is also referred to as a CPI cover. In some embodiments, the cover layers 032 in the display modules shown in FIGS. 1 and 2 are UTG covers.

In some embodiments of the present disclosure, still referring to the partial film layer diagram shown in FIG. 4, it can be seen that a thickness of the second cover layer 032-2 (i.e., the CPI cover) is less than a thickness of the first cover layer 032-1 (i.e., the UTG cover). It is noted that the thickness directions in the embodiments of the present disclosure are all perpendicular to the carrying surface of the display panel 01.

In some embodiments, the thickness of the UTG cover is greater than or equal to 30 micrometers (μm), and the thickness of the CPI cover ranges from 2 μm to 4 μm. In some embodiments, referring to FIG. 4, in the display module shown in FIG. 4, the thickness of the UTG cover is 30 mm and the thickness of the CPI cover is 4 μm.

In some embodiments, FIG. 4 also illustrates a single UTG cover in the case that the CPI cover is not disposed. Further, in the case that the CPI cover is coated on a side of the single UTG cover, and a heat curing process is performed on the double-layer cover plate, the warping magnitude of the cover plate is increased.

It should be noted that, in conjunction with FIG. 1, in the case that only the first hardened coating layer 033 (i.e., HC1 layer) is disposed, i.e., the second hardened coating layer 034 (i.e., HC2 layer) is not disposed and only one UTG cover is disposed, a positive warping phenomenon occurs on the display module due to the uneven stress, i.e., the display panel 01 is arched towards the side away from the support layer 02. Combined with the process flow shown in FIG. 4, it can be seen that, in the case that a CPI cover is disposed on a side of the UTG cover, a negative warping phenomenon occurs on the UTG cover (i.e., arched toward the side close to the display panel 01.) The negatively warped UTG counteracts the shrinkage of the first hardened coating layer 033 and reduces the positive warping magnitude of the first protective cover plate cover1, thereby avoiding the unevenness of the film layer and avoiding the problem of the light and shadow being unsmooth.

It should be noted that the implementation shown in FIG. 4 is understood as coating CPI on UTG for the first protective cover plate cover1. That is, the CPI cover is coated on one side of the UTG cover, such that the positive warping caused by the shrinkage of the HC1 layer is counteracted by the negative warping of the cover plate, so as to ensure the flatness of the first protective cover plate cover1.

The following embodiments are all illustrated with the display module including one layer of UTG cover as an example.

In some embodiments of the present disclosure, the material of the second hardened coating layer 034 (i.e., the HC2 layer) and the material of the first hardened coating layer 033 (i.e., the HC1 layer) are the same.

In some embodiments of the present disclosure, the thickness of the second hardened coating layer 034 is less than the thickness of the first hardened coating layer 033.

In some embodiments, the thickness of the first hardened coating layer 033 ranges from 5 μm to 8 μm, and the thickness of the second hardened coating layer 034 ranges from 3 μm to 4 μm. In some embodiments of the present disclosure, the first hardened coating layer 033 of the display module has a thickness of 8 μm, and the second hardened coating layer 034 of the display module has a thickness of 3 μm.

In some embodiments of the present disclosure, the protective cover plate 03 includes: a second hardened coating layer 034 disposed on a side, close to the display panel 01, of each release layer 031. In this way, the formed protective cover plate 03 is ensured to be sufficiently flat, thereby more effectively avoiding the problem of light and shadow being unsmooth of the display module.

In some embodiments of the present disclosure, referring to FIGS. 1 to 4, it can also be seen that the protective cover plate 03 includes: a first release layer 031-1 and a second release layer 031-2 sequentially stacked in a direction close to the display panel 01, i.e. two release layers 031 in total.

In some embodiments, the material of the release layer 031 includes polyethylene terephthalate (PET), and accordingly, the release layer 031 is also referred to as a PET layer. For the purpose of differentiation, the first release layer 031-1 is referred to as a PET1 layer and the second release layer 031-2 is referred to as a PET2 layer.

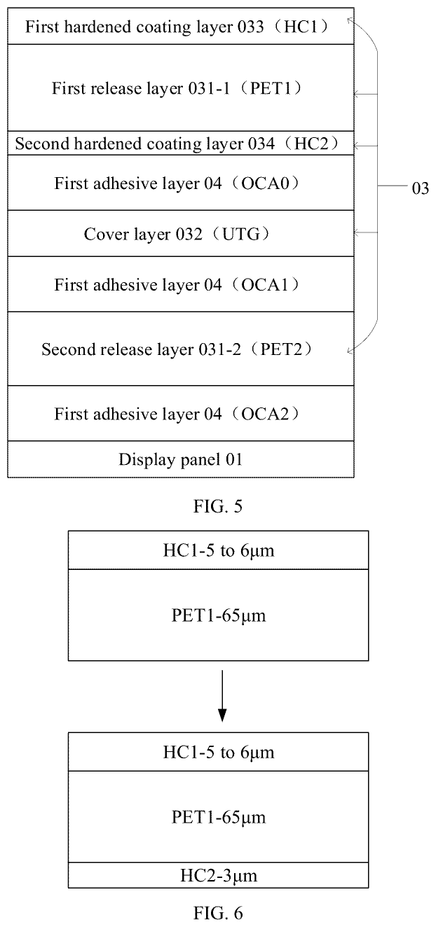

In some embodiments, with reference to the structural diagram of still another display module shown in FIG. 5 and the partial diagram of film layers illustrated in FIG. 6, it can be seen the following.

The protective cover plate 03 according to some embodiments of the present disclosure includes a second hardened coating layer 034 disposed on a side, close to the display panel 01, of the first release layer 031-1. That is, on the basis of disposing the HC1 layer on the side, away from the display panel 01, of the first release layer 031-1, an HC2 layer is further disposed on the side, close to the display panel 01, of the first release layer 031-1. This implementation is understood as HC double-sided coating for the first protective cover plate cover1. A test result shows that by performing HC double-sided coating, the HC1 layer and the HC2 layer counteract each other's stresses, making the stresses balanced, thereby forming a flat first protective cover plate cover1 and avoiding the problem of light and shadow being unsmooth.

In some embodiments, Table 1 below shows the pre-baking warping magnitudes and post-baking warping magnitudes in millimeters (mm) of different positions of the display module under two scenarios. The two scenarios are respectively disposing only the first hardened coating layer 033 on the side, away from the display panel 01, of the first release layer 031-1 (i.e., HC single-sided coating) at present and performing the HC double-sided coating as described in the embodiments of the present disclosure. Here, the heating condition includes heating for 70 minutes (min) at 60 degrees and subsequently cooling for 2 hours (h).

TABLE 1

| | Thickness | Thickness | Pre-baking warping magnitude/mm | | | | Post-baking warping magnitude/mm | | | |
|---|---|---|---|---|---|---|---|---|---|---|
| | of HC1/ | of HC2/ | Upper | Upper | Lower | Lower | Upper | Upper | Lower | Lower |
| Scenario | mm | mm | left | right | Left | right | left | right | Left | right |
| HC | 5.76/ | 0 | 7 | 8 | 6.5 | 7.5 | 12 | 13.5 | 14 | 12.2 |
| single- | 5.83/ | | | | | | | | | |
| sided | 5.85/ | | | | | | | | | |
| coating | 5.68 | | | | | | | | | |
| HC | 5.76/ | 3.3/ | 6 | 5.5 | 7 | 6.5 | 0.5 | 0.5 | 0 | 0.5 |
| double- | 5.83/ | 3.5/ | | | | | | | | |
| sided | 5.85/ | 3.4/ | | | | | | | | |
| coating | 5.68 | 3.3 | | | | | | | | |

Taking the display module in a rectangular shape as an example, warping magnitudes of a total of four different positions of the display module are shown in Table 1 above, the four positions including upper left (i.e., top left), upper right (i.e., top right), lower left (i.e., bottom left), and lower right (i.e., bottom right). Further, a total of four different HC coating thicknesses are tested in Table 1. The thicknesses of HC1 (i.e., the first hardened coating layer 033) include 5.76 mm, 5.83 mm, 5.85 mm, and 5.68 mm, and the thicknesses of the corresponding coated HC2 (i.e., the second hardened coating layer 034) include 3.3 mm, 3.5 mm, 3.4 mm, and 3.3 mm. Furthermore, with reference to Table 1, it can be seen that, using the related techniques of HC single-sided coating, the post-baking warping magnitude increases relative to the pre-baking warping magnitude; but using the HC double-sided coating method of the embodiments of the present disclosure, the post-baking warping magnitude is made to further decrease relative to the pre-baking warping magnitude, e.g., regarding the upper left position, the pre-baking warping magnitude being 6 mm, and the post-baking warping magnitude being reduced to 0.5 mm. It can be further seen that the embodiments of the present disclosure, by adopting the HC double-sided coating method, form a relatively flat first protective cover plate cover1, thereby facilitating avoiding the problem of light and shadow being unsmooth.

In some embodiments, in the display module illustrated in FIG. 6, the thickness of the PET1 layer is 65 μm, the thickness of the HC1 layer ranges from 5 μm to 6 μm, and the thickness of the HC2 layer is 3 μm.

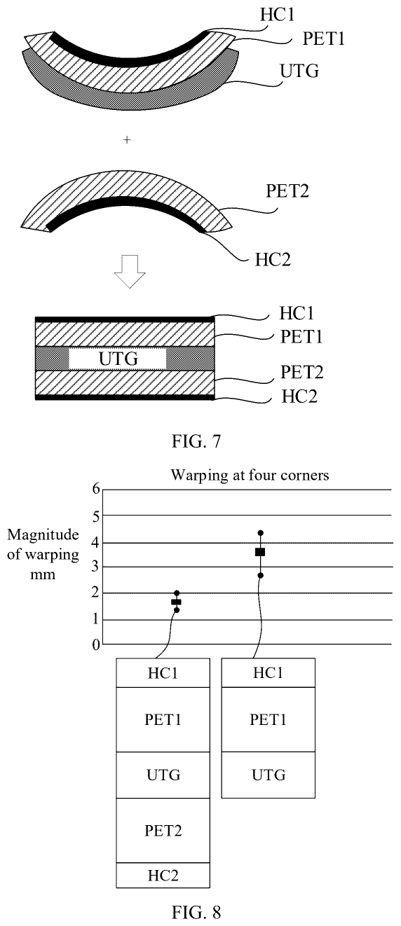

In some other embodiments, with reference to the partial diagrams of film layers illustrated in FIGS. 2 and 7, it can be seen the following.

The protective cover plate 03 in the embodiments of the present disclosure includes: a second hardened coating layer 034 disposed on a side, close to the display panel 01, of the second release layer 031-2. That is, on the basis of disposing the HC1 layer on the side, away from the display panel 01, of the first release layer 031-1, the HC2 layer is further disposed on the side, close to the display panel 01, of the second release layer 031-2. It should be noted that in the display module illustrated in FIG. 6, the HC2 layer is not disposed on the side, close to the display panel 01, of the first release layer 031-1. This implementation is also understood as providing a hard shrinkage coating for the second protective cover plate cover2, such that the second protective cover plate cover2 is negatively warped.

Referring to the partial diagram of film layers shown in FIG. 7, it can also be seen that for the first protective cover plate cover on which the first release layer 031-1 and the first hardened coating layer 033 (i.e., the PET1 layer+the HC1 layer) are sequentially stacked on a UTG cover, a positive warping phenomenon occurs due to the uneven stress. In the embodiments of the present disclosure, the second protective cover plate cover2 is disposed on a side of the UTG cover, the second protective cover plate cover2 including the second release layer 031-2 and the second hardened coating layer 034 (i.e., a PET2 layer+an HC2 layer) that are sequentially stacked along the direction close to the display panel 01, such that stress counteraction is achieved by virtue of the negative warping phenomenon of the second protective cover plate cover2 and the positive warping phenomenon of the first protective cover plate cover1, so as to form a flatter protective cover plate 03, and thus avoid the problem of light and shadow being unsmooth.

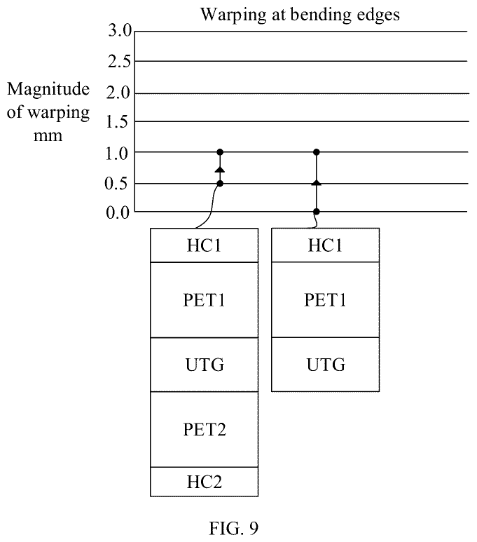

In some embodiments, taking the display module having a rectangular shape as an example, FIG. 8 illustrates a warping magnitude comparison of four corners of the display module under two scenarios, the two scenarios being respectively disposing a hard shrinkage coating for the second protective cover plate cover2 and disposing the HC1 layer only on the side, away from the display panel 01, of the first release layer 031-1 (i.e., the hard shrinkage coating is not disposed for the second protective cover plate cover2). FIG. 9 illustrates a warping magnitude comparison of the bending edges of the display module under these two scenarios.

With reference to FIG. 8, it can be seen that in the scenario in which the second protective cover plate cover2 is not provided with the hard shrinkage coating, the magnitudes of warping at the four corners approximately range from 3 mm to 4 mm; and in the case that the second protective cover plate cover2 is provided with the hard shrinkage coating, the magnitudes of warping at the four corners are reduced to about 2 mm.

Referring to FIG. 9, it can be seen that in the scenario in which the second protective cover plate cover2 is not provided with the hard shrinkage coating, the magnitudes of warping at the bending edges approximately range from 0 mm to 1 mm; and in the case that the second protective cover plate cover2 is provided with the hard shrinkage coating, the magnitudes of warping at the bending edges are maintained at approximately 0.5 mm to 1 mm.

It is to be noted that, under the scenario of light and shadow being unsmooth of related art, the spacing between the support layer 02 and the display panel 01 approximately ranges from 40 μm to 123 μm. In the embodiments of the present disclosure, on the basis of avoiding the problem of light and shadow being unsmooth, the above spacing is further reduced to less than 80 μm. Therefore, it can also be further seen that the arching of the display panel is alleviated, and the film layer of the display module is relatively flat.

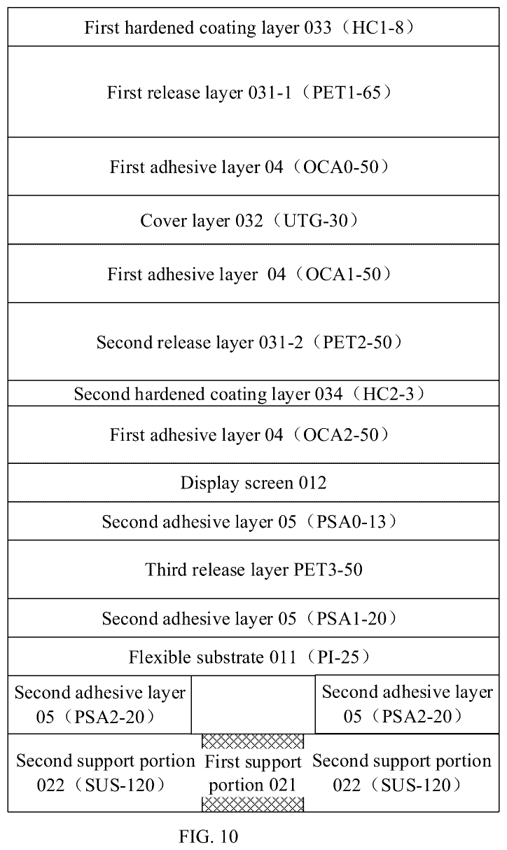

In some embodiments of the present disclosure, with reference to the schematic structural diagram of film layers of still another display module illustrated in FIGS. 1 and 10, it can also be seen that the display panel 01 includes: a flexible substrate 011 and a display screen 012 sequentially stacked in a direction away from the support layer 02. Referring to FIG. 1, it can be seen that the display screen 012 further includes a back film Ufilm and a main body screen (PNL) sequentially stacked.

In some embodiments, the material of the flexible substrate 011 includes polyimide PI, and accordingly, the flexible substrate 011 is also referred to as a PI layer, as shown in FIG. 10.

In some embodiments of the present disclosure, still referring to FIGS. 1 to 7 and FIG. 10, it can also be seen that the display module further includes:

a first adhesive layer 04, disposed between two adjacent film layers in the display panel 01 and the protective cover plate 03 and configured to adhere the two adjacent film layers; and

a second adhesive layer 05 disposed between two adjacent film layers in the display panel 01 and the support layer 02 and configured to adhere the two adjacent film layers.

In some embodiments, as can be seen from FIGS. 1 and 10, the display module includes: a first adhesive layer 04 disposed between the display screen 012 and the second release layer 031-2, a first adhesive layer 04 disposed between the second release layer 031-2 and the cover layer 032, and a first adhesive layer 04 disposed between the cover layer 032 and the first release layer 031-1. In some embodiments, the display module further includes: a second adhesive layer 05 disposed between the flexible substrate 011 and the support layer 03, and a second adhesive layer 05 disposed between the flexible substrate 011 and the display screen 012. In addition, in some embodiments, with reference to FIG. 10, it can also be seen that a third release layer PET3 is disposed between the second adhesive layer 05 and the display screen 012, and accordingly, a second adhesive layer 05 configured to adhere the third release layer PET3 to the display screen 012 is further provided.

In some embodiments of the present disclosure, in conjunction with FIG. 10, the first adhesive layer 04 includes: a transparent optically clear adhesive (OCA). The second adhesive layer 05 includes a pressure-sensitive adhesive (PSA). In this way, the light-exiting reliability of the light-exiting surface of the display panel 01 is ensured.

For the purpose of differentiation, the first adhesive layers 04 from the side away from the support layer 02 to the side close to the support layer 02 (i.e., from top to bottom) in the drawings are respectively symbolled as OCA0, OCA1, and OCA2; and the second adhesive layers 05 from top to bottom are respectively symbolled as PSA0, PSA1, and PSA2.

Further, in some embodiments, with reference to FIGS. 1 and 10, it can also be seen that an orthographic projection of the second adhesive layer 05 (i.e., PSA2) disposed between the flexible substrate 01 and the support layer 02 on the display panel 01 is overlapped with an orthographic projection of the second support portion 022 of the support layer 02 on the display panel 01, and is not overlapped with an orthographic projection of the first support portion 021 of the support layer 02 on the display panel 01. That is, the above second adhesive layer 05 is configured to adhere the flexible substrate to the second support portion 022 of the support layer 02. It is to be noted that the design of cutting off the above second adhesive layer 05 at the bending region A1 is also referred to as an adhesive-cutoff design.

In some embodiments of the present disclosure, still referring to FIG. 1, it can also be seen that the display module further includes: a waterproof protective film TPU disposed between the second support portion 022 and the flexible substrate 01.

The TPU refers to a material of the waterproof protective film, including thermoplastic polyurethane elastomer (i.e., Thermoplastic Urethane). That is, there is no adhesive material disposed between the TPU and the support layer 03.

In some embodiments of the present disclosure, the material of the support layer 02 includes steel use stainless SUS (also referred to as stainless steel.) In some embodiments, as shown in FIG. 10, the orthographic projection of the first support portion 021 on the display panel 01 is reticulate.

In some embodiments of the present disclosure, still referring to FIG. 10, it can be seen that in the display module, the thickness of the first release layer 031-1 (i.e., the PET1 layer) is about 65 μm; the thickness of the second release layer 031-2 (i.e., the PET2 layer) is about 50 μm; the thickness of the third release layer PET3 is about 50 μm; the thickness of the transparent optically clear adhesive OCA is about 50 μm; the thickness of the pressure-sensitive adhesive PSA is about 20 μm or 13 μm; the thickness of the flexible substrate 011 is about 25 μm; the thickness of the back film Ufilm of the display screen 012 is about 65 μm; and the thickness of the main body screen PNL is about 43 μm. Of course, the thicknesses herein are only schematic illustrations.

Combined with the above embodiments, it can be seen that in the embodiments of the present disclosure, to alleviate the problem of light and shadow being unsmooth due to the positive warping phenomenon of the structure shown in FIG. 1, the following implementations can be applied. First, an HC double-sided coating is performed on the first protective cover plate cover1, so as to achieve stress offset and make the stress balanced, and to form a relatively flat first protective cover plate cover1. Second, the design of coating CPI on UTG is performed for the first protective cover plate cover1, such that the negative warping phenomenon of the cover layer offsets the shrinkage of the first hardened coating layer HC1, thereby alleviating the positive warping of the first protective cover plate cover1. Third, the hardened coating layer HC2 is added for the second protective cover plate cover2, such that the second protective cover plate cover2 is negatively warped, and in the case that the second protective cover plate cover2 is attached to the positively warped first protective cover plate cover1, the stresses are offset and a flatter protective cover plate is formed. Based on the above, on the basis of forming a flat protective cover plate, the problem of light and shadow being unsmooth of the current display module is effectively avoided. It is to be noted that the above multiple implementations can be combined in any combination so as to achieve better improvement.

In summary, the embodiments of the present disclosure provide a display module. The display module includes: a display panel including a bending region and a non-bending region, and a protective cover plate and a support layer respectively disposed on a side of a light-exiting surface and a side of a back surface of the display panel. The protective cover plate includes not only a plurality of release layers sequentially stacked and a first hardened coating layer disposed on a side, away from the display panel, of the plurality of release layers, but also at least one cover layer disposed between two adjacent release layers and a second hardened coating layer disposed on a side, close to the display panel, of at least one release layer. In this way, stress offsetting is achieved by virtue of the warping of the cover layer and the second hardened coating layer and the warping of the first hardened coating layer, and thus a relatively flat protective cover plate is formed. On the basis of the formation of the flat protective cover plate, the problem that the display module is prone to warping is alleviated, and no visible and obvious arch occurs at the time of the display module reflecting external light, thereby effectively avoiding the problem of light and shadow being unsmooth in the display module.

FIG. 11 is a method for manufacturing a display module according to some embodiments of the present disclosure. The method is applicable to manufacturing a display module as shown in any one of FIGS. 2 to 7 and FIG. 10. As shown in FIG. 11, the method includes the following processes.

In Process 1101, a display panel is provided, wherein the provided display panel includes a bending region and a non-bending region surrounding the bending region.

In process 1102, a support layer is formed on a side, away from a light-exiting surface of the display panel, of the display panel, wherein the formed support layer includes a first support portion disposed on a side of the bending region and a second support portion disposed on a side of the non-bending region, the first support portion including a skeleton region and being spaced apart from the display panel, and the second support portion being in contact with the display panel.

In process 1103, a protective cover plate is formed on a side of the light-exiting surface of the display panel, wherein the formed protective cover plate includes a plurality of release layers sequentially stacked in a direction away from the display panel, at least one cover layer disposed between two adjacent release layers in the plurality of release layers, a first hardened coating layer disposed on a side, away from the display panel, of the plurality of release layers, and a second hardened coating layer disposed on a side, close to the display panel, of at least one release layer of the plurality of release layers.

In some embodiments, a material of the formed second hardened coating layer is the same as a material of the first hardened coating layer.

In some embodiments, the formed second hardened coating layer has a thickness less than a thickness of the first hardened coating layer.

In some embodiments, the formed protective cover plate includes a second hardened coating layer disposed at a side, close to the display panel, of each of the plurality of release layers.

In some embodiments, the formed protective cover plate includes a first release layer and a second release layer sequentially stacked in a direction close to the display panel.

In some embodiments, the formed protective cover plate includes a first cover layer and a second cover layer sequentially stacked in a direction close to the display panel.

In some embodiments, both a material of the first cover layer and a material of the second cover layer include a transparent flexible material, and the material of the first cover layer is different from the material of the second cover layer.

In some embodiments, the material of the first cover layer includes transparent glass; and the material of the second cover layer includes colorless polyimide.

In some embodiments, a thickness of the formed second cover layer is less than a thickness of the first cover layer.

In some embodiments, the formed display panel includes a flexible substrate and a display screen sequentially stacked in a direction away from the support layer; and the method further includes:
forming, between two adjacent film layers in the display panel and the protective cover plate, a first adhesive layer configured for adhering the two adjacent film layers in the display panel and the protective cover plate; and
forming, between two adjacent film layers in the display panel and the support layer, a second adhesive layer configured for adhering the two adjacent film layers in the display panel and the support layer;
wherein an orthographic projection of a second adhesive layer formed between the flexible substrate and the support layer on the display panel is overlapped with an orthographic projection of the second support portion of the support layer on the display panel and is not overlapped with an orthographic projection of the first support portion of the support layer on the display panel. Accordingly, the formed second adhesive layer is configured to adhere the flexible substrate to the second support portion of the support layer.

In some embodiments, the method further includes:
forming a waterproof protective film between the second support portion and the flexible substrate.

In some embodiments, the formed first adhesive layer includes a transparent optically clear adhesive; and the formed second adhesive layer includes a pressure-sensitive adhesive.

In some embodiments, a material of the formed support layer includes stainless steel; and an orthographic projection of the first support portion on the display panel is reticulate.

In summary, the embodiments of the present disclosure provide a method for manufacturing a display module. The display module formed by the method includes a display panel including a bending region and a non-bending region, and a protective cover plate and a support layer respectively disposed on a side of a light-exiting surface and a side of a back surface of the display panel. The protective cover plate includes not only a plurality of release layers sequentially stacked and a first hardened coating layer disposed on a side, away from the display panel, of the plurality of release layers, but also at least one cover layer disposed between two adjacent release layers and a second hardened coating layer disposed on a side, close to the display panel, of at least one release layer. In this way, stress offsetting is achieved by virtue of the warping of the cover layer and the second hardened coating layer and the warping of the first hardened coating layer, and thus a relatively flat protective cover plate is formed. On the basis of the formation of the flat protective cover plate, the problem that the display module is prone to warping is alleviated, and no visible and obvious arch occurs at the time of the display module reflecting external light, thereby effectively avoiding the problem of light and shadow being unsmooth in the display module.

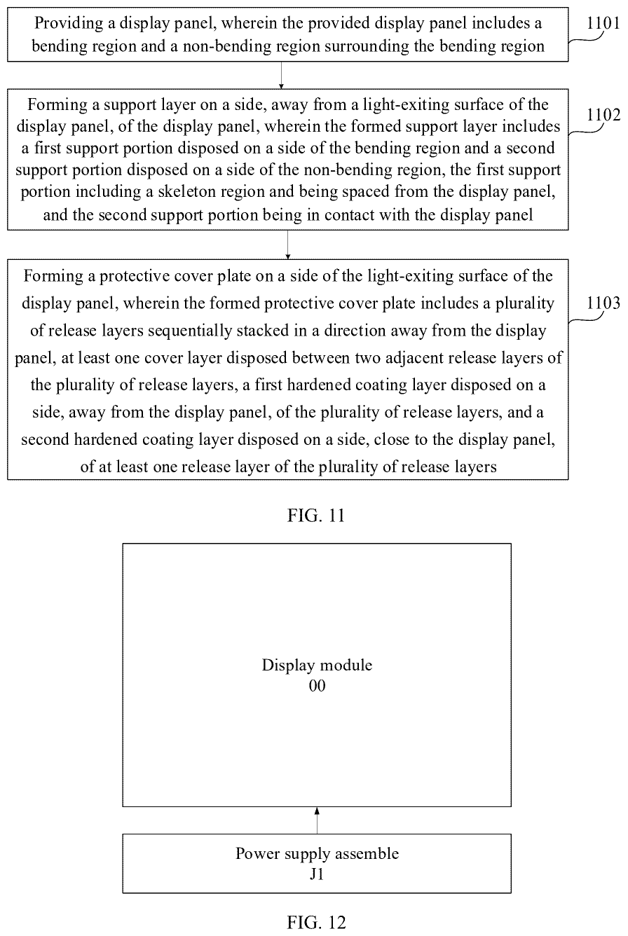

FIG. 12 is a schematic structural diagram of a display device according to some embodiments of the present disclosure. As shown in FIG. 12, the display device includes: a power supply assembly J1, and a display module 00 as shown in any one of FIGS. 2 to 7 and 10.

The power supply assembly J1 is coupled (i.e., electrically connected) to the display module 00 and configured to supply power to the display module 00.

In some embodiments of the present disclosure, the display device includes: a cellular phone, a tablet computer, a flexible display device, a television set, a monitor, or any other product or component having a display function.

It should be understood that the terms used in the embodiments of the present disclosure are used for the purpose of explaining the embodiments of the present disclosure and are not intended to limit the present disclosure. Unless otherwise defined, technical or scientific terms used in the embodiments of the present disclosure should have the ordinary meaning understood by a person of ordinary skill in the art to which the present disclosure belongs.

In the description and the claims of the present disclosure, the terms “first,” “second,” “third,” or the like are used for distinguishing different components only and are not to be construed as indicating or implying any sequence, number, or relative importance.

Similarly, similar terms such as “one” or “a” do not indicate a quantitative limitation, but indicate the existence of at least one object.

Similar terms such as “include” or “comprise” mean that the element or object appearing before “include” or “comprise” covers the element, object, or their equivalents appearing behind “include” or “comprise”, but do not exclude other elements or objects.

The terms “up,” “down,” “left,” or “right” are used only to indicate relative positional relationships, and in the case that the absolute position of the described object is changed, the relative positional relationship is also possible to change accordingly.

The foregoing are only optional embodiments of the present disclosure, and are not intended to limit the present disclosure, and any modifications, equivalent substitutions, improvements, etc. made within the concept and principles of the present disclosure shall be included in the scope of protection of the present disclosure.

1. A display module, comprising:
a display panel, wherein the display panel comprises a bending region and a non-bending region surrounding the bending region;
a support layer disposed on a side, away from a light-exiting surface of the display panel, of the display panel, wherein the support layer comprises a first support portion disposed on a side of the bending region and a second support portion disposed on a side of the non-bending region, the first support portion comprising a skeleton region and being spaced apart from the display panel, and the second support portion being in contact with the display panel; and
a protective cover plate disposed on a side of the light-exiting surface of the display panel, wherein the protective cover plate comprises a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed at a side, close to the display panel, of at least one release layer of the plurality of release layers.

2. The display module according to claim 1, wherein a material of the second hardened coating layer is the same as a material of the first hardened coating layer.

3. The display module according to claim 1, wherein the second hardened coating layer has a thickness less than a thickness of the first hardened coating layer.

4. The display module according to claim 3, wherein the thickness of the first hardened coating layer ranges from 5 μm to 8 μm; and the thickness of the second hardened coating layer ranges from 3 μm to 4 μm.

5. The display module according to claim 1, wherein the protective cover plate comprises a second hardened coating layer disposed at a side, close to the display panel, of each of the plurality of release layers.

6. The display module according to claim 1, wherein the protective cover plate comprises a first release layer and a second release layer sequentially stacked in a direction close to the display panel.

7. The display module according to claim 6, wherein the protective cover plate comprises a first hardened coating layer disposed on a side, away from the display panel, of the first release layer, and a second hardened coating layer disposed on a side, close to the display panel, of the first release layer.

8. The display module according to claim 6, wherein the protective cover plate comprises a first hardened coating layer disposed on a side, away from the display panel, of the first release layer, and a second hardened coating layer disposed on a side, close to the display panel, of the second release layer.

9. The display module according to claim 1, wherein the protective cover plate comprises a first cover layer and a second cover layer sequentially stacked in a direction close to the display panel.

10. The display module according to claim 9, wherein both a material of the first cover layer and a material of the second cover layer comprise a transparent flexible material, and the material of the first cover layer is different from the material of the second cover layer.

11. The display module according to claim 10, wherein the material of the first cover layer comprises transparent glass, and the material of the second cover layer comprises colorless polyimide.

12. The display module according to claim 1, wherein a thickness of the second cover layer is less than a thickness of the first cover layer.

13. The display module according to claim 12, wherein the thickness of the first cover layer is greater than or equal to 30 μm; and the thickness of the second cover layer ranges from 2 μm to 4 μm.

14. The display module according to claim 1, wherein a material of any one of the plurality of the release layers comprises polyethylene terephthalate.

15. The display module according to claim 1, wherein the display panel comprises a flexible substrate and a display screen sequentially stacked in a direction away from the support layer; and
the display module further comprises:
a first adhesive layer, disposed between two adjacent film layers in the display panel and the protective cover plate, and configured to adhere the two adjacent film layers; and
a second adhesive layer, disposed between two adjacent film layers in the display panel and the support layer and configured to adhere the two adjacent film layers;
wherein an orthographic projection of a second adhesive layer disposed between the flexible substrate and the support layer on the display panel is overlapped with an orthographic projection of the second support portion of the support layer on the display panel and is not overlapped with an orthographic projection of the first support portion of the support layer on the display panel, and the second adhesive layer is configured to adhere the flexible substrate to the second support portion of the support layer.

16. The display module according to claim 15, further comprising:
a waterproof protective film disposed between the second support portion and the flexible substrate.

17. The display module according to claim 15, wherein the first adhesive layer comprises a transparent optically clear adhesive; and the second adhesive layer comprises a pressure-sensitive adhesive.

18. The display module according to claim 1, wherein a material of the support layer comprises stainless steel; and an orthographic projection of the first support portion on the display panel is reticulate.

19. A method for manufacturing a display module, applicable to manufacturing the display module as defined in claim 1, the method comprising:
providing a display panel, wherein the display panel comprises a bending region and a non-bending region surrounding the bending region;
forming a support layer on a side, away from a light-exiting surface of the display panel, of the display panel, wherein the formed support layer comprises a first support portion disposed on a side of the bending region and a second support portion disposed on a side of the non-bending region, the first support portion comprising a skeleton region and being spaced from the display panel, and the second support portion being in contact with the display panel; and
forming a protective cover plate on a side of the light-exiting surface of the display panel, wherein the formed protective cover plate comprises a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed on a side, close to the display panel, of at least one release layer of the plurality of release layers.

20. A display device, comprising: a power supply assembly and a display module;
wherein the power supply assembly is coupled to the display module and is configured to supply power to the display module; and
the display module comprises:
a display panel, wherein the display panel comprises a bending region and a non-bending region surrounding the bending region;
a support layer disposed on a side, away from a light-exiting surface of the display panel, of the display panel, wherein the support layer comprises a first support portion disposed on a side of the bending region and a second support portion disposed on a side of the non-bending region, the first support portion comprising a skeleton region and being spaced apart from the display panel, and the second support portion being in contact with the display panel; and
a protective cover plate disposed on a side of the light-exiting surface of the display panel, wherein the protective cover plate comprises a plurality of release layers sequentially stacked in a direction away from the display panel, at least one cover layer disposed between two adjacent release layers of the plurality of release layers, a first hardened coating layer disposed on a side, away from the display panel, of the plurality of release layers, and a second hardened coating layer disposed at a side, close to the display panel, of at least one release layer of the plurality of release layers.
